(19) United States
(12) Patent Application Publication
(10) Pub. No.: US 2025/0079276 A1
(43) Pub. Date: Mar. 6, 2025

(54) STIFFENER WITH INTEGRATED CONNECTORS

(71) Applicants: Advanced Micro Devices, Inc., Santa Clara, CA (US); XILINX, INC., San Jose, CA (US)

(72) Inventors: Manish DUBEY, Austin, TX (US); Frank Peter LAMBRECHT, San Jose, CA (US); Brett P. WILKERSON, Austin, TX (US); Deepak Vasant KULKARNI, Austin, TX (US); Hemanth Kumar DHAVALESWARAPU, Austin, TX (US); Priyal SHAH, Bangalore (IN)

(21) Appl. No.: 18/241,140

(22) Filed: Aug. 31, 2023

(51) Int. Cl. H01L 23/498; H01L 23/00; H01L 23/043; H01L 25/065; H05K 1/14

(52) U.S. Cl. CPC H01L 23/49816; H01L 23/043; H01L 24/16; H01L 25/0657; H05K 1/141; H01L 2224/16055; H01L 2224/16225; H01L 2225/06517; H01L 2225/0652; H01L 2924/1431; H01L 2924/1434; H05K 2201/10189; H05K 2201/10325

(57) ABSTRACT

Disclosed herein is a chip package assembly that includes a package substrate coupled with an integrated circuit die, a stiffener attached to a top surface of the package substrate, and a connector assembly integrated with the stiffener. Both the connector assembly and the stiffener are disposed at a peripheral area of the top surface. The connector assembly includes a bracket and a connector. The connector is configured to connect with one or more optical cables or electrical connectors. The bracket may be formed by a cavity in the stiffener. The bracket may be attached to the top surface of the package substrate. The stiffener may be coupled with the bracket directly or via the connector. Additionally, a frame coupled to the stiffener or a PCB board may be used to secure the bracket in place.

### TECHNICAL FIELD

Embodiments of the present invention generally relate to a chip package assembly, and in particular, to chip package assembly having a stiffener integrated with a connector assembly and electronic devices having the same.

### BACKGROUND

The adoption of high speed serializer/deserializer (“SERDES”) channels in an IC package has run into many issues due to losses associated with long route lengths, skin effects, insufficient ground referencing, power intermixing etc. Co-packaged optics, such as flyover cables, and electrical connectors are used in an IC package to launch the signal from the chip package with minimal loss. However, the addition of connector assemblies on the top side of an IC package requires large real estate and lead to an undesirable increase of the size of the IC package.

Therefore, a need exists for an improved chip package which can accommodate additional connector assemblies without substantially increasing the size of the package.

### SUMMARY

Disclosed herein are chip package assembly having a stiffener integrated with a connector assembly and electronic devices having the same. In one example, a chip package assembly includes a package substrate coupled with an integrated circuit die, a stiffener attached to a top surface of the package substrate, and a connector assembly integrated with the stiffener. Both the connector assembly and the stiffener are disposed at a peripheral area of the top surface. The connector assembly includes a bracket and a connector. The connector is configured to connect with and/or secure one or more optical cables or electrical connectors. The bracket may be formed by a cavity in the stiffener. The bracket may be attached to the top surface of the package substrate. The stiffener may be coupled with the bracket directly or via the connector. Additionally, a frame coupled to the stiffener or a PCB board may be used to secure the bracket in place.

In some examples, the chip package assembly includes a bracket comprises a first part of a retaining mechanism, and a stiffener comprises a second part of the retaining mechanism, and the first part and the second part engage with each other.

In some examples, the stiffener includes cantilever extensions configured to engage with the bracket.

In some examples, the stiffener includes cantilever extensions configured to engage with the bracket.

In some examples, a bracket is coupled with the stiffener via the connector.

In some examples, retainers secure the connector to the stiffener. The retainers may include fasteners attaching the connector to the stiffener. The retainers may include a leg with one end bent outwardly relative to the bracket. The leg may include protrusions configured to engage with the stiffener.

In some examples, the chip package assembly may further comprise a frame coupled to the stiffener and configured to retain the bracket, wherein the frame comprises a cutout configured to allow the connector to go through, and the frame is attached to atop surface of the stiffener.

In some examples, the chip package assembly, the chip package assembly may further comprise a lid disposed on a planar member, the planar member being configured to pivot around a hinge to open and close the lid, the connector being disposed on the planar member.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an electronic device having a chip package assembly with a stiffener according to an embodiment of the present application.

FIG. 2 is a schematic top view of the electronic device depicted in FIG. 1 according to an embodiment of the present application.

FIG. 3 is a schematic top view of an electronic device that includes a chip package assembly having a stiffener with integrated connector assemblies according to an embodiment of the present application.

FIG. 4 is a schematic cross-sectional view of a connector assembly according to an embodiment of the present application.

FIG. 5 is a schematic top view of a stiffener with integrated brackets according to an embodiment of the present application.

FIG. 6A is a schematic perspective view of a coupling mechanism between a stiffener and a receptacle according to an embodiment of the present application.

FIG. 6B is a schematic cross-sectional view of a coupling mechanism between a stiffener and a connector assembly according to an embodiment of the present application.

FIG. 6C is a schematic cross-sectional view of a coupling mechanism between a stiffener and a connector assembly according to an embodiment of the present application.

FIG. 6D is a schematic cross-sectional view of a coupling mechanism between a stiffener and a connector assembly according to an embodiment of the present application.

FIG. 7 is a schematic cross-sectional view of a retaining mechanism for a connector assembly according to an embodiment of the present application.

FIG. 8A is a schematic cross-sectional view of a retaining mechanism for a connector assembly according to an embodiment of the present application.

FIG. 8B is a schematic top view of a retainer for a connector assembly according to an embodiment of the present application.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A chip package assembly is disclosed that includes a connector assembly integrated having a stiffener. The connector assembly can be used to connect flyover cables for transmitting high speed data or to connect other electronic components. The connector assembly includes a bracket and a detachable connector. The bracket may be mounted on a package substrate and may be coupled directly with the stiffener to maintain the mechanical integrity of the stiffener. To avoid being pulled by the flyover cables, the bracket may be coupled with the stiffener via the detachable connector which is configured to shield the bracket from the pulling force from the flyover cables. The integration between the connector assembly and the stiffener as set forth not only reduces the size of a chip package that has a plurality of connector assemblies, but also maintains the warpage resistance of the stiffener.

Auxiliary retaining mechanisms, such as metal frames, may be optionally coupled to the stiffener or a PCB board to secure the connector assembly in place. The connector assembly is not limited only being connected to the stiffener. Other components for a chip package, such as heat sinks, may be integrated to the stiffener to save real estate on the surface of the chip package.

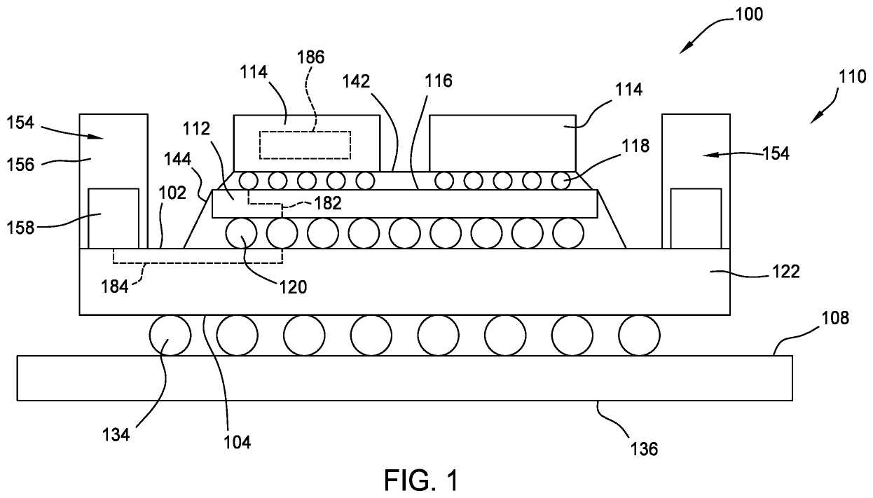

Turning now to FIG. 1, an exemplary integrated chip package assembly 110 is disposed on a printed circuit board (PCB) 136. The chip package assembly 110 and the PCB 136 together form at least part of an electronic device 100. The electronic device 100 may be a tablet, computer, copier, digital camera, smart phone, control system, automated teller machine, server or other solid-state memory and/or logic device. The chip package assembly 110 includes one or more IC die 114 mounted to an interposer 112. For example, FIG. 1 shows two IC dice 114 are mounted on the interposer 112 side by side. Alternatively, the IC die 114 may be stacked directly on each other and then mounted on an interposer. In other embodiments, the IC die 114 may be mounted directly to the package substrate 122 without the presence of an interposer 112.

The interposer 112 includes circuitry 186 for electrically connecting functional circuitry 186 of the dice 114 to a circuitry 184 of the package substrate 122. The circuitry of the interposer 112 may optionally include transistors and/or other circuit elements. Solder connections 120, also known as or “package bumps” or “C4 bumps,” are utilized to provide an electrical connection between the circuitry of the interposer 112 and the circuitry of the package substrate 122. A bottom surface 104 of the package substrate 122 may be mounted and connected to a top surface 108 of the PCB 136, utilizing solder balls 134, wire bonding or other suitable technique. An undermolding 144 may be utilized to fill the space not taken by the solder connections 120 between the PCB 136 and the interposer 112.

The IC dice 114 may be programmable logic devices, such as field programmable gate arrays (FPGA), memory devices, optical devices, processors or other IC logic structures. Optical devices include photo-detectors, lasers, optical sources, and the like. In the example depicted in FIG. 1, the IC dice 114 are mounted to a top surface 116 of the interposer 112 by die connections 118. The die connections 118 may be in the form of a plurality of solder joints, also known as “micro-bumps”. The circuitry of the interposer 112 connects the die connections 118 to selective solder connections 120, and hence, connects selective circuitry of each IC die 114 to the package substrate 122, to enable communication of the dice 114 with the PCB 136 after the chip package assembly 110 is mounted within the electronic device 100.

According to an embodiment, a stiffener 154 is coupled to the package substrate 122 and configured to enhance the warpage resistance of the package substrate 122 against out of plane deformation. The stiffener 154 is generally positioned at the peripheral area, such as edges, of the package substrate 122. The stiffener 154 includes a plurality of walls 156, which may be fabricated from any materials that are suitable to reinforce the stiffness of the package substrate 122. In an example, the walls 516 may be fabricated from a combination of materials selected from metals, ceramics, thermoplastics, glass reinforced plastics, and carbon reinforced materials. The stiffener 154 may have a ring shape, be fabricated in one or more attached sections, or be fabricated in one more attached spaced apart sections.

A connector assembly 158 is integrated with the stiffener 154. In one example, the connector assembly 158 secured with or by the stiffener 154 to the package substrate 122. The connector assembly 158 is electrically connected (i.e., communicatively coupled) to the functional circuitry 186 of at least one or more of the IC dice 114 via the circuitry 184 of the package substrate 122 (and the circuitry 182 of the interposer 112, when present).

According to an embodiment, a connector assembly 158 is integrated with the walls 156 of the stiffener 154. In one example, the connector assembly 158 is configured to provide connection to a flyover cable or other components of the chip package 110. The connector assembly 158 is integrated with the walls 156 in a manner that does not substantially weaken the warpage resistance of the stiffener 154 and does not occupy an additional large area outside the footprint of the stiffener 154. According to an embodiment, certain components of the connector assembly 158, such as a bracket, may be formed as an integral part of the walls 156. In one example, the bracket represents a cavity in the walls 156. After the bracket is formed in the walls 156, a connector is subsequently coupled with the bracket, thus interlocking the connector assembly 158 with the stiffener 154. According to another embodiment, the connector assembly 158 may also be fabricated separately and then mechanically or chemically coupled to the walls 156, thus interlocking the connector assembly 158 with the stiffener 154.

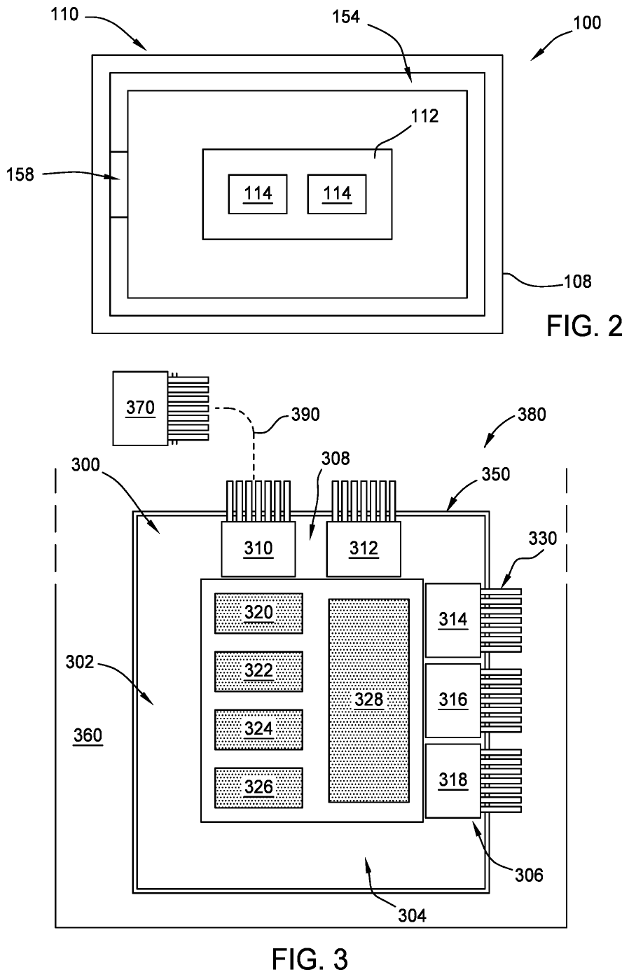

As shown in FIG. 2, the stiffener 154 is generally disposed around the perimeter of the package substrate 122. The stiffener 154 may be a single continuous ring, be made from a plurality of wall segments, or be made from a plurality of spaced-apart wall segments. According to an embodiment, the stiffener 154 forms an enclosure that surrounds the IC dies 114. The connector assembly 158 integrated with the stiffener 154 is also shown in FIG. 2. According to an embodiment, the connector assembly 158 is configured to have a footprint substantially bounded by the walls of the stiffener 154 to reduce the size of the chip package 110. According to an embodiment, the chip package 110 may include auxiliary retaining mechanisms configured to fasten the connector assembly 150 to the chip package 110, thus interlocking the connector assembly 158 with the stiffener 154.

FIG. 3 illustrates a schematic top view of an electronic device 380 that includes a chip package assembly 350, the chip package assembly 350 having a stiffener 300 having at least one or more connector assemblies according to an embodiment. The electronic device 380 also includes an IC die 370 that is in communication with the chip package assembly 350 through the circuitry of a printed circuit board 360. The IC die 370 may be mounted to or be remove from the printed circuit board 360. In one example, the die 370 be disposed within another electronic device, such as a server, computer, expansion card, mother or daughter board, memory device, display, or other solid state device, that is communicatively coupled, for example via cables, optics, wireless or other type of connection, with the printed circuit board 360. In another example, the IC die 370 be mounted directly to the printed circuit board 360, and thus integrated with the chip package assembly 350 in a single electronic device 380.

The chip package assembly 350 includes a plurality of IC dies 320-328 mounted to a substrate 340. The stiffener 300 is also mounted to the substrate 340. The stiffener 300 is integrated with one or more one or more connector assemblies, shown as connector assemblies 310, 312, 314, 316, 318 in FIG. 3. However, other number of connector assemblies may alternatively be utilized. The connector assemblies 310, 312, 314, 316, 318 are coupled to the stiffener 300, for example, using an adhesive, such as an epoxy. The connector assemblies 310, 312, 314, 316, 318 are electrically coupled to the circuitry of the substrate 340 such that the connector assemblies 310, 312, 314, 316, 318 are electrically coupled with plurality of IC dies 320-328. A cable 390, such as an optical cable, can be used to connect the IC die 370 disposed outside of the chip package assembly 350 with the one or more of the IC dies 320-328, thus enabling high speed communication out of the chip package assembly 350 to components such as the IC die 370 remote from or part of the electronic device 380.

In the example depicted in FIG. 3, the stiffener 300 includes a plurality of wall segments 302-308 enclosing a plurality of IC dies 320-328. The wall segment 308 includes two connector assemblies 310 and 312, and the wall segment 306 includes three connector assemblies 314-316. In an examples, the connector assemblies connect flyover cables, such as the cable 390. The wall segments 302 and 304 include no connector assemblies. As shown in FIG. 3, each connector assembly 310-318 is connected with multiple cables, for example seven cables, and is integrated with a corresponding wall segment. A fewer or greater number of connector assemblies may be integrated with the stiffener 300, and that the connector assemblies may be disposed at any desired locations of the stiffener 300. The number and locations of these connector assemblies are selected such that the warpage resistance of the stiffener may not be substantially weakened by these connector assemblies. According to an embodiment, other types of components of a chip package may be integrated into the wall segments of a stiffener, such as heat sinks or other fasteners,

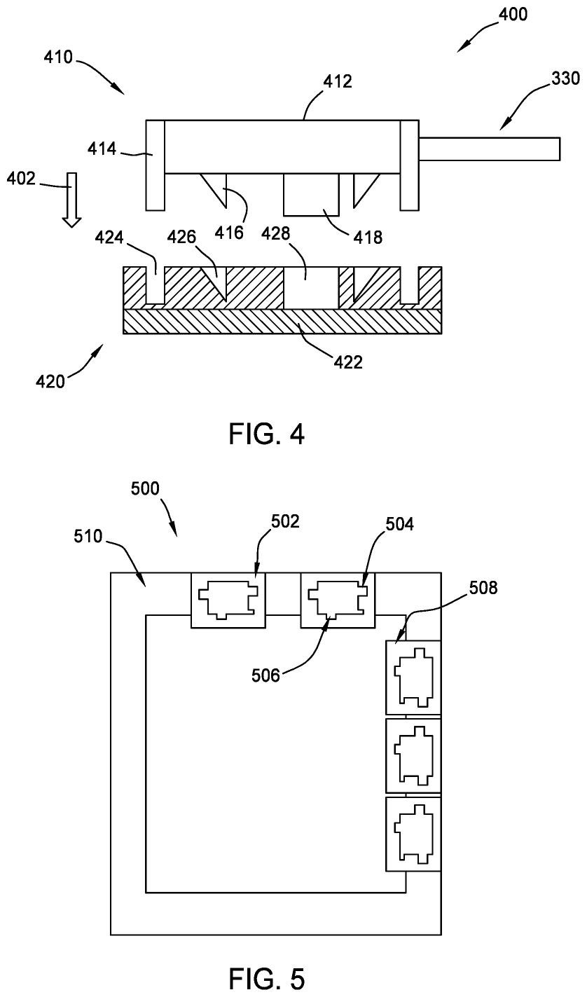

FIG. 4 illustrates a schematic cross-sectional view of a flyover cable assembly 400 according to an embodiment. The flyover cable assembly 400 may be used as the cable 300 depicted in FIG. 3. The flyover cable assembly 400 includes a connector 410 configured to connect a plurality of cables 330. The flyover cable assembly 400 also includes a bracket 420 attached or mounted to the package substrate (not shown). The connector 410 and the bracket 420 couple with each other and form the flyover cable assembly 400. The connector 410 includes a housing 412, a plurality of male plugs 414 and 416, and a plurality of pins 418. The bracket 420 includes a housing 422, a plurality of female sockets 424 and 426, and a receptacle 428. When the connector 410 is pressed toward the bracket 420 along the direction 402, the plurality of pins 418 are accepted by the receptacle 428, and the plurality of male plugs 414, 416 are mated with the plurality of female sockets 424, 426. The male plugs and the female sockets form a retaining mechanism that retains the connector 410 within the bracket 420. According to an embodiment, the retaining mechanism allows the male plugs and the female sockets to decouple so that the connector 410 and the bracket 420 are detachable from each other. It is contemplated that other types of retaining mechanisms may be used to couple the connector 410 with the bracket 420, such as fasteners, such as screws, adhesives, latches, and clips.

FIG. 5 illustrates a stiffener with integrated brackets according to an embodiment. The stiffener 500 as shown in FIG. 5 may be understood as a “one-piece” integration as the bracket represents an integral part of the stiffener. As shown in FIG. 5, the stiffener 500 includes a plurality of walls 510. According to an embodiment, the plurality of brackets 502 represent perforations or cavity in the walls 510 of the stiffener and include a plurality of depressions and protrusions 504 and 506 to retain a mating connector. In this way, the brackets 502 can be formed as part of the stiffener 500 and does not require any additional components or parts to be separately made. Fabricating methods, such as drilling, molding, or imprinting, may be used to create the brackets 502 in the stiffener 500.

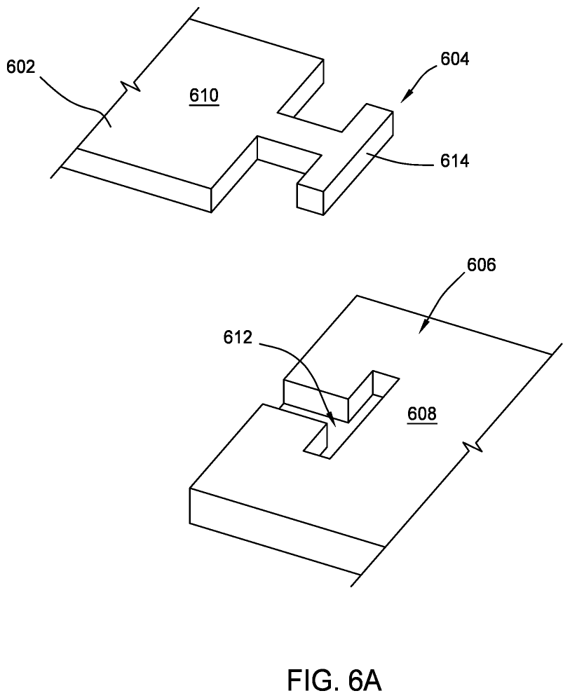

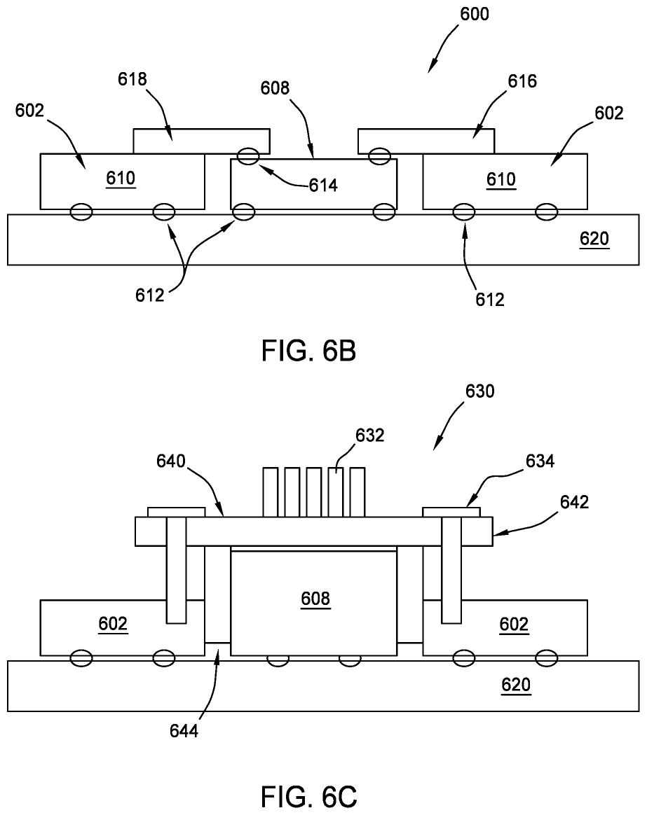

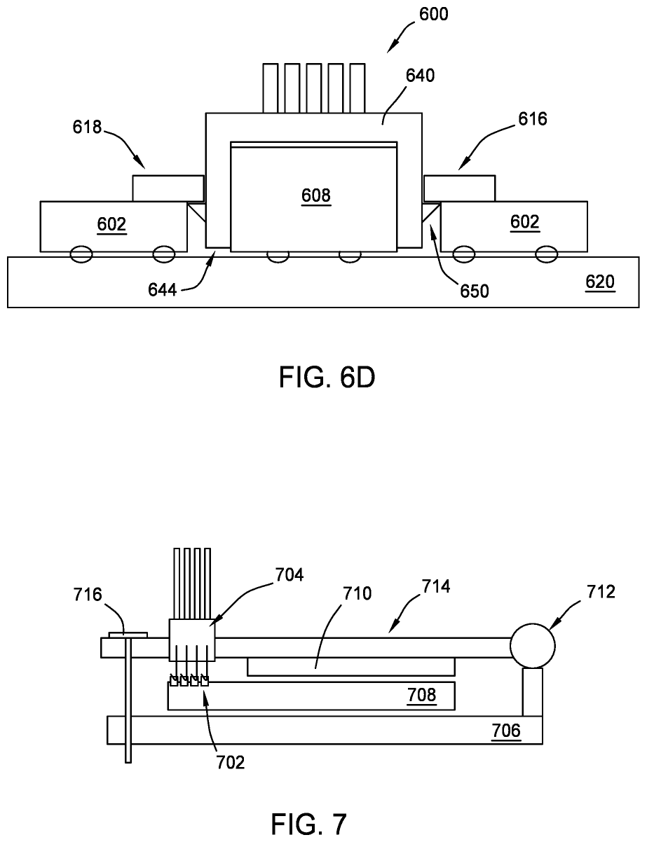

Although the “one-piece” design for integrating a connector assembly to a stiffener avoids making a separate bracket, the manufacturing process of the stiffener may become more complex and the mechanical strength of the stiffener may be weakened when many connector assemblies are integrated. Thus, the following FIGS. 6A-6D illustrate various “multiple piece” configurations for a connector assembly in which the bracket is separately made and then coupled with the stiffener by various mechanisms.

FIG. 6A illustrates an embodiment of an integration configuration according to an embodiment. A stiffener 602 includes a plurality of wall segments 610 connected by brackets 608. A retaining mechanism is formed between the wall segments and the brackets, in which one part of the retaining mechanism is formed in the wall segments and the other part of the retaining mechanism is formed in the brackets. The retaining mechanism interlocks the connector assembly 158 with the stiffener 602. As shown in FIG. 6A, one stiffener wall segment 610 is contiguous to a bracket 608 of a connector assembly. The stiffener segment 610 includes an end 604 that is configured to mate with an end 606 of the bracket 608. To form a retaining mechanism, the end 604 has a T-shaped extrusion 614 that mates with a T-shaped slot 612 in the ends 606 of the bracket 608. It is contemplated that other retaining mechanisms, such as adhesive, solder, latches, clips, and buckles, may be implemented to couple the bracket 608 and the stiffener segment 610, thus interlocking the connector assembly with the stiffener 602.

FIG. 6B illustrate another embodiment of an integration configuration 600 according to an embodiment. As shown in FIG. 6B, the stiffener 602 includes a plurality of wall segments 610 that are separated by a bracket 608 of a connector assembly. The wall segments 610 and the bracket 608 are attached to the package substrate 620 by any suitable attachment mechanisms 612, such as solder or adhesives. As the wall segments 610 are separated by the bracket 608, the warpage resistance of the stiffener 602 may be weakened. According to an embodiment, the wall segments 610 may include extensions 616 and 618, which are attached with the bracket 608 by any suitable attachment mechanisms 614, such as solder, adhesives, fasteners or latches. The extensions 616 and 618 may be made of the same material as the wall segments 610 and include cantilever beams extending from ends of the wall segments 610 to above the bracket 608. As shown in FIG. 6B, the extensions 616 and 618 are attached only to the bracket 608 without engaging the connector. According to an embodiment, the extensions 616 and 618 may be configured to be attached to both the connector and the bracket of a connector assembly. For example, the extensions 618 and 616 may be shaped to conform with the contour of a connector assembly such that the extensions 618 and 616 can be attached to both the connector and the bracket 608.

A connector assembly to be integrated with the stiffener generally has a small form factor. As a result, the bracket of the connector assembly is also small and has a relatively small contact area with a package substrate. If the bracket is constantly subject to the pull form by the connector, the bracket may be detached from the package substrate. In addition, the stiffener may also transmit certain warpage force generated by the package substrate to the connector assembly. Thus, it may be beneficial to protect a bracket of a connector assembly from unnecessary stress, such as those created by the connector and cables.

FIGS. 6C and 6D illustrate connector assemblies whose connectors are integrated to a stiffener according to an embodiment. Turning to FIG. 6C, a connector assembly 630 includes a connector 640, a bracket 608, and attachment mechanisms. A plurality of cables 632 are connected with the connector 640 and may be subject to pull force from time to time. Similar as shown in FIG. 6B, the bracket 608 and the wall segment 610 of the stiffener 602 are attached to the package substrate. But the wall segments 610 are not directly attached to the bracket 608. Instead, the wall segments 610 are attached to the connector 640 which, in turn, is coupled with the bracket 608. The connector 640 is configured to shield the bracket 608 from stress exerted by the cable 632 and/or the wall segment 610. According to an embodiment, the attachment mechanisms of the connector assembly 630 includes a plurality of fasteners that fasten a cantilever part 642 of the connector 640 to the wall segments 610. The attachment mechanism of the connector assembly 630 may also include a leg 644 which is elastic and has an end bent outwardly relative to the bracket 608. After the leg 644 is pushed into the gap between the bracket 608 and the wall segments 610, the leg 644 will tightly contact the wall segments 610. With this configuration, the stress exerted by the wall segments 610 and the cables 632 can be effectively transmitted to the stiffener 602 and shielded from the bracket 608.

Turning to FIG. 6D, the attachment mechanisms of the connector assembly 600 further includes a protrusion 650 disposed at the leg 644. The protrusion 650 is configured to engage with the extensions 618 and 616 to retain the connector 640. According to an embodiment, the protrusion 650 includes a beveled surface facing the package substrate which helps the leg 644 to be pushed inward when the connector 640 is pushed into the bracket 608. The protrusion 650 further includes a flat surface opposite to the beveled surface and engages with a bottom surface of the extensions 616 and 618 after the connector 640 is pushed into the bracket 608. The flat surface of the protrusion 650 retains the connector 640 in the bracket 608.

FIG. 7 illustrates an embodiment of a connector assembly retained by a support and retaining module of a chip package according to an embodiment. In certain designs, a chip package may have a lid mounted on a support and retaining module to cover and protect the IC dies. As shown in FIG. 7, a chip package includes a PCB board 706, a package substrate 708 supporting a plurality of IC dies, and a lid 710 for covering the chip package, and a support and retaining module (SRM) configured to protect the chip package. In an example, the SRM module may be a stiffening mechanism in an LGA socket. The SRM module includes a hinge 712, a planar member 714, and a retaining mechanism 716. The lid 710 is attached to the planar member 714 which can pivot around the hinge 712 to open and close the lid 710. When the lid 710 is closed, the retaining mechanism 716 is used to retain the lid 710 and the planar member 714 in a closed position. According to an embodiment, the bracket 702 of an assembly is integrated to the stiffener of the package substrate 708, while the connector 704 of the assembly is disposed on the planar member 714 of the SRM module. When the lid 710 is closed, the connector 704 and the bracket 702 are engaged with each other. In this way, the SRM module can be used to keep the connector assembly in place and further shield the bracket 702 from unwanted forces.

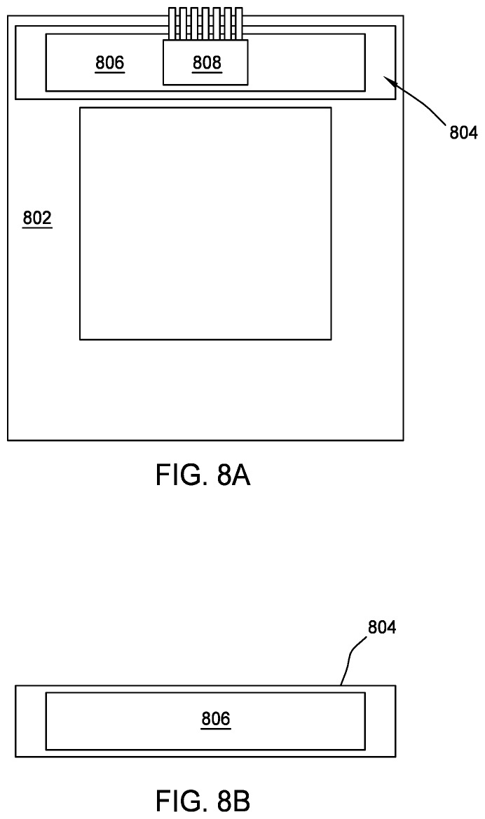

FIGS. 8A and 8B illustrate auxiliary retainers that can be additionally used to secure the bracket of a connector assembly on a stiffener according to an embodiment. A metal frame 804 is attached to the stiffener 802 and is configured to engage with and secure a bracket (not shown) in place. The metal frame 804 includes a cutout area 806 that allows connectors 808 to be freely connected with or disconnected from the bracket. The two ends of the metal frame 804 may be attached to the top surface of the stiffener 802 or the side walls of the stiffener 802.

While the foregoing is directed to embodiments of the present invention, other and further embodiments of the invention may be devised without departing from the basic scope thereof, and the scope thereof is determined by the claims that follow.

What is claimed is:

1. A chip package assembly comprising:
a package substrate coupled with an integrated circuit die;
a stiffener attached to a top surface of the package substrate outward of the integrated circuit die; and
a connector assembly integrated with the stiffener and communicatively coupled with functional circuitry of the integrated circuit die through a circuitry of the package substrate.

2. The chip package assembly according to claim 1, wherein both the connector assembly and the stiffener are disposed at a peripheral area of the top surface.

3. The chip package assembly according to claim 2, wherein the connector assembly and the stiffener are configured to substantially enclose the integrated circuit die.

4. The chip package assembly according to claim 3, wherein the connector assembly is configured to connect to an optical cable.

5. The chip package assembly according to claim 1, wherein the connector assembly comprises:
a bracket and a connector, the bracket is formed by a cavity of the stiffener.

6. The chip package assembly according to claim 5, wherein the cavity is configured to retain the connector.

7. The chip package assembly according to claim 1, wherein the connector assembly comprises:
a bracket and a connector, the bracket is attached to the top surface of the package substrate.

8. The chip package assembly according to claim 7, wherein the bracket and the stiffener are coupled to each other directly.

9. The chip package assembly according to claim 8, wherein the bracket comprises a first part of a retaining mechanism, the stiffener comprises a second part of the retaining mechanism, and the first part and the second part engage with each other.

10. The chip package assembly according to claim 8, wherein the stiffener comprises cantilever extensions configured to engage with the bracket.

11. The chip package assembly according to claim 7, wherein the connector comprises retainers that secure the connector to the stiffener.

12. The chip package assembly according to claim 1, wherein the connector assembly further comprises:
a bracket and a connector, the bracket coupled to the stiffener by a frame,
wherein the frame comprises a cutout configured to allow the connector to go through, and the frame is attached to atop surface of the stiffener.

13. The chip package assembly according to claim 1, further comprising a lid disposed on a planar member, the planar member being configured to pivot around a hinge to open and close the lid, a connector of the connector assembly disposed on the planar member.

14. An electronic device comprising:
a chip package assembly comprising:
a package substrate coupled with an integrated circuit die;
a stiffener attached to a top surface of the package substrate outward of the integrated circuit die; and
a connector assembly integrated with the stiffener and communicatively coupled with functional circuitry of the integrated circuit die through a circuitry of the package substrate;
a remote integrated circuit die disposed outside of the chip package assembly; and
a cable connecting the remote integrated circuit die with the connector assembly of the chip package assembly.

15. The electronic device of claim 14, wherein the cable is an optical cable.

16. The electronic device of claim 14, wherein the remote integrated circuit die and the chip package assembly are coupled to a common printed circuit board.

17. The electronic device of claim 14, wherein the chip package assembly and the the remote integrated circuit die are not coupled to a common printed circuit board.

18. The electronic device of claim 14, wherein the connector assembly is secured to or by the stiffener.

19. A method of assembling a chip package assembly, the method comprising:
mounting one or more integrated circuit dies to a substrate; and
mounting a stiffener to the substrate outward of the one or more integrated circuit dies; and
securing a connector assembly to the chip package assembly via the stiffener, the connector assembly electrically coupled to functional circuitry of the one or more integrated circuit dies via the substrate.

20. The method of claim 19, wherein securing the connector assembly further comprises:
interlocking the stiffener with the connector assembly.
